(19) United States
(12) Patent Application Publication
(10) Pub. No.: US 2010/0149884 A1
(43) Pub. Date: Jun. 17, 2010

(54) REDUCTION OF POWER CONSUMPTION IN A MEMORY DEVICE DURING SLEEP MODE OF OPERATION

(75) Inventor: Ashish Kumar, Jharkhand (IN)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics Pvt. Ltd., Greater Noida (IN)

(21) Appl. No.: 12/616,296

(22) Filed: Nov. 11, 2009

(30) Foreign Application Priority Data
Nov. 11, 2008 (IN) 2560/DEL/2008

(51) Int. Cl. G11C 5/14

(52) U.S. Cl. 365/189.09; 365/227

(57) ABSTRACT

The present disclosure relates to a system comprising memory device with a power switch where the system comprises a first voltage controlled switch coupling positive power supply to positive supply terminal of memory device core; a second voltage controlled switch coupling negative power supply to negative supply terminal of the memory device core; a first reference voltage coupled to the substrate terminal of said first voltage controlled switch; and a second reference voltage coupled to the substrate terminal of said second voltage controlled switch. This helps maintain a sufficient RNM for efficient performance by the system.

### CROSS REFERENCE TO RELATED APPLICATIONS

This application claims the priority benefit of Indian patent application number 2560/Del/2008, filed on Nov. 11, 2008, entitled “REDUCTION OF POWER CONSUMPTION IN A MEMORY DEVICE DURING SLEEP MODE OF OPERATION” which is hereby incorporated by reference to the maximum extent allowable by law.

### BACKGROUND OF THE INVENTION

1. Field of the Invention

The present disclosure relates to memory devices and more specifically to reduction of power consumption in a memory device during sleep mode of operation.

2. Discussion of the Related Art

The terms ‘stand by’ and ‘sleep mode’ have been used interchangeably throughout the present disclosure.

Memories comprise several memory columns comprising memory cells for storage and access of data. However, each column conducts a leakage current which increases with increase in the supply voltage of the memory. Larger the memory size, more the leakage current and power consumption by the memory.

To counter the effect of leakage and improve the performance of the device comprising said memory, stand by voltage of memory is reduced. When the stand by voltage is reduced, data stored in the memory has to be retained; therefore data retention power gating is used. In such power gating the memory core is switched to sleep mode while maintaining a minimum supply voltage across memory cells. This reduces all main components of leakage.

The difference between a higher voltage being applied at one terminal of a memory core and a lower voltage being applied at the second terminal of the memory terminal is referred to as rail to rail voltage. During the sleep mode, the rail to rail voltage is reduced to maintain a minimum supply voltage so that data is retained. Such reduction of rail to rail voltage results in reduced noise margin of the memory in stand by/sleep mode, measured as retention noise margin (RNM). Sufficient RNM is required for cells in stand by/sleep mode to ensure data integrity once memory is reactivated from stand by/sleep mode. At low voltages, slow process corners, high threshold voltages of diodes used for power gating as well as fast process corners (High Temperatures) of the diodes used for power gating along with high leakage result in low rail to rail voltage. This reduces RNM to unacceptable values.

Process corners above are defined as SS corner condition (slow nmos, slow pmos) and cross corner conditions (slow nmos, fast pmos or fast nmos, slow pmos).

### BRIEF DESCRIPTION OF THE DRAWINGS

Features and aspects of various embodiments of the disclosure will be better understood when the following detailed description is read with reference to the accompanying drawings in which like characters represent like parts throughout the drawings:

FIG. 1 describes a block diagram of a system including a SRAM with a bias generation unit in accordance with an embodiment of the disclosure.

FIG. 2 describes a SRAM including a SRAM memory core and voltage controlled switches according to another embodiment of the disclosure.

FIG. 3 illustrates use of virtual power planes to provide bias voltage to first and second voltage controlled switch in accordance with an embodiment of the present disclosure.

FIG. 4 describes a bias generation unit used to provide bias voltage to first and second voltage controlled switch in accordance with an embodiment of the present disclosure.

FIG. 5 illustrates a reference bias generation unit to provide bias voltage to first and second voltage controlled switch in accordance with an embodiment of the present disclosure.

FIG. 6 describes a method of reducing power consumption in a SRAM during sleep mode of operation in accordance with an embodiment of the disclosure.

### DETAILED DESCRIPTION OF THE DRAWINGS

The embodiments of the present disclosure will be described in detail with reference to the accompanying drawings. However, the present disclosure is not limited to these embodiments. The present disclosure can be modified in various forms. The embodiments of the present disclosure described herein are only provided to explain more clearly the present disclosure to the ordinarily skilled in the art. In the accompanying drawings, like reference numerals are used to indicate like components.

Various embodiments of the disclosure teach a system comprising a memory device with a bias generation unit. The system comprises a first voltage controlled switch coupling positive power supply to positive supply terminal of memory device core and a second voltage controlled switch coupling negative power supply to negative supply terminal of the memory device core. A first reference voltage provides a bias to the substrate terminal of the first voltage controlled switch. Similarly, a second reference voltage provides bias to the substrate terminal of the second voltage controlled switch.

All embodiments of the present disclosure are illustrated with SRAM (Static Random Access Memory). However, such illustrations do not limit the scope of the present disclosure as it is applicable to all volatile memories such as SRAM (Static Random Access Memory), DRAM (Dynamic Random Access Memory) and a few ROM architectures.

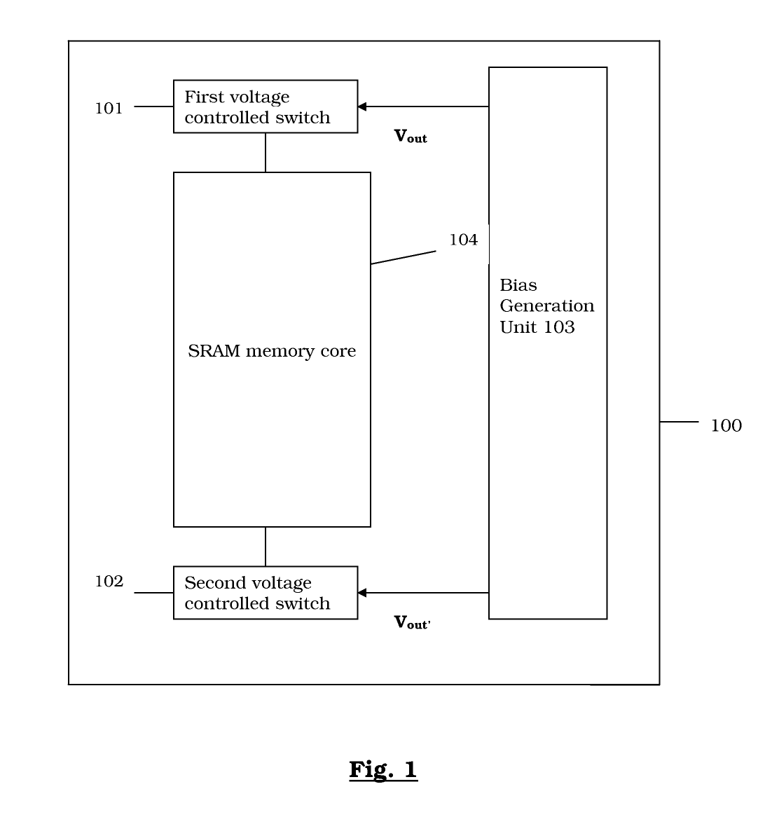

FIG. 1 illustrates the block diagram representation of a system 100 including SRAM with bias generation unit according to an embodiment of the invention. The system 100 includes a SRAM with an SRAM memory core 104 coupled to a bias generation unit 103. The bias generation unit ensures that the SRAM memory core 104 switches to stand by/sleep mode of operation to reduce leakage in the memory. The system 100 further comprises a first voltage controlled switch 101 coupling a positive power supply to positive power supply terminal of SRAM memory core. Similarly, a second voltage controlled switch 102 couples a negative power supply to the negative power supply terminal of SRAM memory core. First and second reference voltages Vₒᵤₜ, V_{out′} are coupled to substrate terminals of the first and second voltage controlled switches 101, 102 respectively. The reference voltages Vₒᵤₜ, V_{out′} are a function of the threshold voltages of the voltage controlled switches 101, 102 respectively. Bias provided by the reference voltages to the respective voltage controlled switches is proportional to the variation in the threshold voltage of the switch. Due to the bias provided, effective retention noise margin (RNM) is increased during sleep mode of operation of the memory.

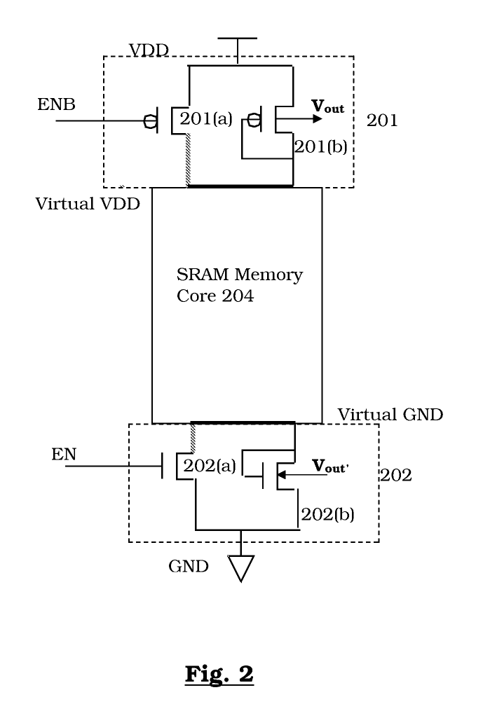

FIG. 2 illustrates a SRAM including SRAM memory core 204 with voltage controlled switches according to another embodiment of the present disclosure. The figure shows a first voltage controlled switch 201(hereinafter referred to as switch 201) coupling positive power supply VDD to positive power supply terminal of the SRAM memory core 204 through virtual VDD. The switch 201 comprises a first forward biased diode 201(b) in parallel with a P channel MOS transistor 201(a) enabled by signal ENB. Similarly, a second voltage controlled switch 202(hereinafter referred to as switch 202) coupling negative power supply GND to negative power supply terminal of the SRAM memory core 204 through virtual GND is included in SRAM. The switch 202 further comprises a second forward biased diode 202(b) in parallel with an N channel MOS transistor 202(a) enabled by signal EN.

A first reference voltage V_{out′} function of threshold voltage of diode 201(b), is applied to the substrate terminal of the diode 201(b). In accordance with an embodiment of the disclosure, the reference voltage Vₒᵤₜ provides a bias to the bulk node of the diode 201(b). As the threshold voltage of diode 201(b) increases, the bias provided by first reference voltage Vₒᵤₜ decreases and due to feedback configuration of the voltage controlled switch 201, the effective threshold voltage of diode 201(b) decreases. Similarly, a second reference voltage Vout′, a function of the threshold voltage of the diode 202(b), is applied to the substrate terminal of the diode 202(b). As the threshold voltage of diode 202(b) increases, the bias provided by second reference voltage 202(b) increases and effective threshold voltage of diode 201(b) decreases, thereby increasing the leakage to maintain sufficient retention noise margin (RNM) at process corners.

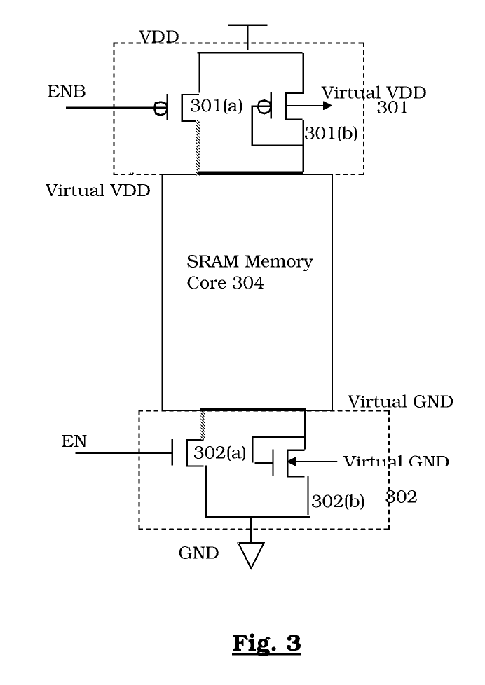

FIG. 3 illustrates use of virtual power planes to provide bias voltage to first and second voltage controlled switch in accordance with an embodiment of the present disclosure. A first voltage controlled switch 301 coupling positive power supply VDD to positive power supply terminal of SRAM memory core 304 through virtual VDD is shown. A second voltage controlled switch 302 coupling negative power supply to negative power supply terminal of SRAM memory core 304 through virtual GND is also included. The voltage controlled switches 301 and 302 are provided a first and second reference voltage at their respective substrate terminal. In the present embodiment of the disclosure, the first reference voltage provided at the substrate terminal of 301 is virtual VDD while the second reference voltage provided at the substrate terminal of 302 is virtual GND.

The first voltage controlled switch 301 comprises a first forward biased diode 301(b) in parallel with a P channel MOS transistor 301(a) enabled by signal ENB (where ENB is a complementary signal of EN). The second voltage controlled switch 302 comprises a second forward biased diode 302(b) in parallel with an N channel MOS transistor 302(a) enabled by signal EN. The first and second reference voltages provide a bias at the bulk node of diodes 301(b) and 302(b) respectively.

Addition of bulk bias to p-diode 301(b) from virtual VDD takes care of excessive drop in its value. The biasing of the bulk node of diode 301(b) by virtual VDD reduces the threshold voltage of diode 301(b) and hence prevents virtual VDD from falling to a certain extent. Thus sufficient retention noise margin (RNM) at process corners is maintained.

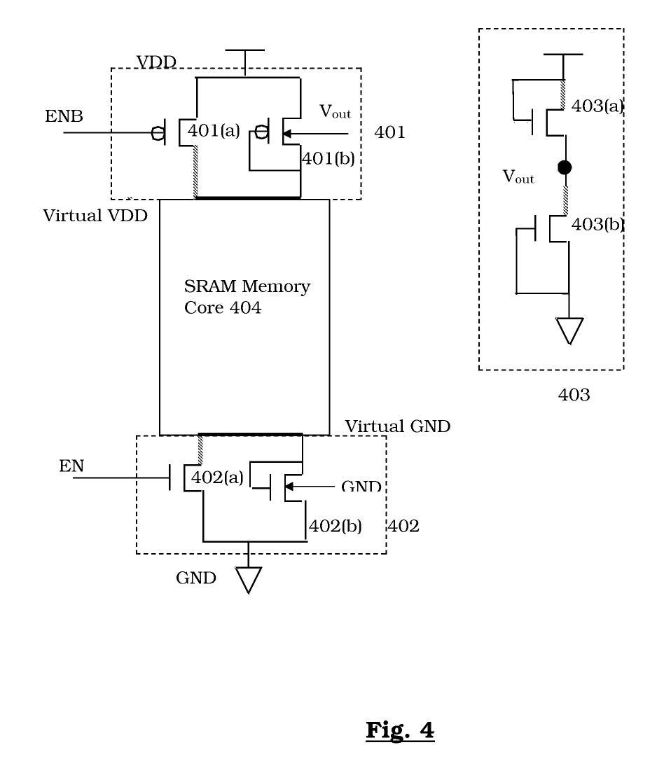

FIG. 4 describes a bias generation unit in accordance with an embodiment of the present disclosure. The bias generation unit is used to provide bias voltage to first and second voltage controlled switch in accordance with an embodiment of the present disclosure. The bias generation unit 403 comprises of two N channel diodes 403(a) and 403(b) where 403(a) is coupled to a positive power supply VDD while 403(b) is ground. The first reference voltage Vₒᵤₜ is generated and applied at the substrate terminal of the first voltage controlled switch 401. The first reference voltage generated provides a bias voltage approximated by Vdd−Vtn for the bulk of diode 401(b). The second reference voltage applied at the substrate terminal of the second voltage controlled switch is GND. Due to feedback configuration of the voltage controlled switch according to the present embodiment of the disclosure, the threshold voltage of diode decreases. Further, virtual VDD level is increased to maintain the retention noise margin (RNM) across the memory.

In another embodiment of the present disclosure, multiple threshold voltage drops for bias are implemented where bulk bias voltage i.e. the reference voltage provided at the diodes is tuned in accordance to the required threshold voltage drop.

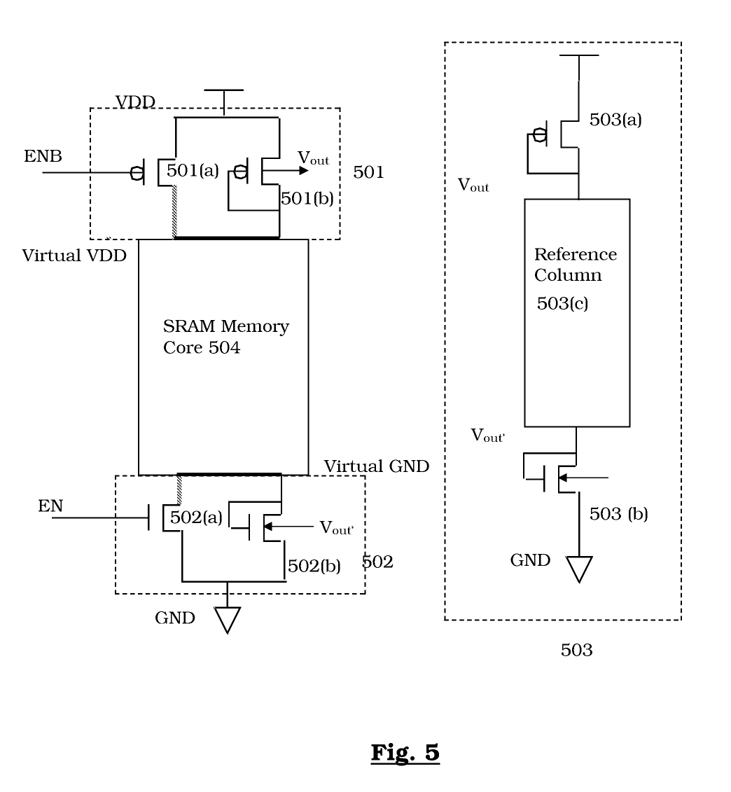

FIG. 5 illustrates a reference bias generation unit to provide a bias voltage to first and second voltage controlled switch in accordance with an embodiment of the present disclosure. The reference bias generation unit 503 comprises a P channel diode 503(a), a N channel diode 503(b) and a reference memory column 503(c). The unit 503 provides first and second reference voltages Vₒᵤₜ and V_{out′} to be coupled to the substrate terminal of first and second voltage controlled switches 501 and 502 respectively. The reference voltages provide a bias voltage to the bulk node of diodes 501(b) and 502(b) respectively.

As the threshold voltage of diode 501(b) increases, the bias provided by first reference voltage Vₒᵤₜ decreases. Effective threshold voltage of diode 501(b) decreases due to feedback configuration of the voltage controlled switch according to an embodiment of the present disclosure. Further, as the threshold voltage of diode 502(b) increases, the bias provided by second reference voltage 502(b) increases. Thereby the effective threshold voltage of diode 501(b) decreases, hence the leakage to maintain sufficient retention noise margin (RNM) at process corners is increased.

However, when desired lowering of threshold voltage for diode 501(b) is large, the direct feedback from virtual VDD is not sufficient. The bias voltage i.e. the reference voltage Vₒᵤₜ is reduced using N-diode/diodes. Depending on the requirement of the threshold voltage swing with increase in threshold voltage of diodes across process corners, number of cells in reference column is multiplied to the columns in the memory i.e.

N′=kN

Where N=number of memcells in Normal column

N′=number of memcells in reference column

k=multiplying factor

According to another embodiment of the present disclosure, a reference bias generation unit provides bias voltage to the first and second voltage controlled unit. The reference bias generation unit in this embodiment comprises only one diode operatively coupled to the reference column. Therefore, in an embodiment of the present disclosure a reference bias generation unit comprises only P-channel diode coupled to reference column while in another embodiment of the present disclosure a reference bias generation unit comprises only N-channel diode coupled to reference column.

In another embodiment of the present disclosure, substrate terminals of voltage controlled switches are biased separately by reference voltages. Separate biasing by means of two columns is useful when better control for the reference voltages is required.

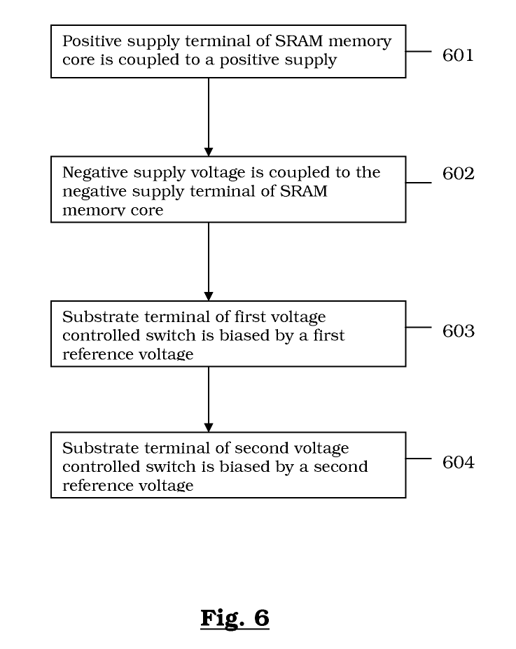

An embodiment of method of reducing power consumption in a SRAM during sleep mode of operation is described in FIG. 6. The method is illustrated as a collection of blocks in a logical flow graph, which represents a sequence of operations that can be implemented in hardware, software, or a combination thereof. The order in which the process is described is not intended to be construed as a limitation, and any number of the described blocks can be combined in any order to implement the process, or an alternate process.

FIG. 6 describes a method of reducing power consumption in a SRAM during sleep mode of operation in accordance with an embodiment of the disclosure. The positive supply terminal of SRAM memory core is coupled to a positive supply 601 while a negative supply voltage is coupled to the negative supply terminal of SRAM memory core 602. The substrate terminal of first voltage controlled switch is biased by a first reference voltage 603. Similarly the substrate terminal of second voltage controlled switch is biased by a second reference voltage 604. The first and second reference voltages are function of threshold voltages of first and second voltage controlled switch respectively.

According to an embodiment of the disclosure, the positive supply coupled to positive supply terminal of SRAM memory core is the supply voltage V_{DD} while the negative supply coupled to negative supply terminal of SRAM memory core is GND.

The disclosure shows and describes only the embodiments of the disclosure; however the disclosure is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the disclosure and to enable others skilled in the art to utilize the disclosure in such, or other, embodiments and with the various modifications required by the particular applications or uses of the disclosure. Accordingly, the description is not intended to limit the disclosure as disclosed herein. Also, it is intended that the appended claims be construed to include alternative embodiments.

1. A system comprising a memory device with a bias generation unit, said system comprising:—
a first voltage controlled switch coupling positive power supply to positive supply terminal of memory device core;
a second voltage controlled switch coupling negative power supply to negative supply terminal of the memory device core;
a first reference voltage coupled to the substrate terminal of said first voltage controlled switch; and
a second reference voltage coupled to the substrate terminal of said second voltage controlled switch.

2. The system as claimed in claim 1 wherein the first voltage controlled switch comprises a first forward biased diode in parallel with a P channel MOS transistor.

3. The system as claimed in claim 1 wherein the second voltage controlled switch comprises a second forward biased diode in parallel with an N channel MOS transistor.

4. The system as claimed in claim 1 wherein the first and second reference voltages are functions of threshold voltage of the first and second voltage controlled switch respectively.

5. A memory device comprising a bias generation unit, said memory device comprising:—
a first voltage controlled switch coupling positive power supply to positive supply terminal of memory device core;
a second voltage controlled switch coupling negative power supply to negative supply terminal of the memory device core;
a first reference voltage coupled to the substrate terminal of said first voltage controlled switch; and
a second reference voltage coupled to the substrate terminal of said second voltage controlled switch.

6. The memory device as claimed in claim 5 wherein the first voltage controlled switch comprises a first forward biased diode in parallel with a P channel MOS transistor.

7. The memory device as claimed in claim 5 wherein the second voltage controlled switch comprises a second forward biased diode in parallel with an N channel MOS transistor.

8. The memory device as claimed in claim 5 wherein the first and second reference voltages are functions of threshold voltage of the first and second voltage controlled switch respectively.

9. A method of reducing power consumption in a memory device during sleep mode of operation comprising the steps of:—
biasing substrate terminal of a first voltage controlled switch to a first reference voltage; and
biasing substrate terminal of a second voltage controlled switch to a second reference voltage.

10. A method as claimed in claim 9 wherein the first and second reference voltages are functions of threshold voltage of the first and second voltage controlled switches respectively.
